(19) United States
(12) Patent Application Publication
(10) Pub. No.: US 2011/0047424 A1
(43) Pub. Date: Feb. 24, 2011

(54) INTEGRATED CIRCUIT INCLUDING A PROGRAMMABLE LOGIC ANALYZER WITH ENHANCED ANALYZING AND DEBUGGING CAPABILITES AND A METHOD THEREFOR

(76) Inventors: James Ray Bailey, Georgetown, KY (US); James Alan Ward, May's Lick, KY (US)

Correspondence Address: LEXMARK INTERNATIONAL, INC.;INTELLECTUAL PROPERTY LAW DEPARTMENT, 740 WEST NEW CIRCLE ROAD, BLDG. 082-1, LEXINGTON, KY, 40550-0999, US

(21) Appl. No.: 12/542,976

(22) Filed: Aug. 18, 2009

(51) Int. Cl. G01R 31/3177; G06F 11/00

(52) U.S. Cl. 714/725; 714/724; 714/E11.002

(57) ABSTRACT

An integrated circuit including a logic analyzer with enhanced analyzing and debugging capabilities and a method therefor. In one embodiment of the present invention, an embedded logic analyzer (ELA) receives a plurality of signals from a plurality of buses within an integrated circuit (IC). The ELA includes an interconnect module to select a trigger signal and/or a sampled signal from the plurality of received signals. A trigger module sets at least one trigger condition and detects if the trigger signal satisfies the at least one trigger condition. When the trigger condition is satisfied, an output module performs at least one task based upon the satisfied at least one trigger condition. If a sampling process is initiated by the output module, the plurality of sampled signals is sampled and may be stored in a memory. The capability of the output module to perform multiple user-defined tasks enhances the debugging capability of the ELA and makes it more versatile.

### BACKGROUND

1. Field of the Invention

The present invention relates generally to an embedded logic analyzer, and particularly to a programmable embedded logic analyzer for analyzing an electronic circuit.

2. Description of the Related Art

A logic analyzer is an electronic instrument that is used to capture and display data signals of an electronic circuit. Generally, the logic analyzer captures the data signals that are too fast to be observed by a user. The user observes the data signals captured by the logic analyzer to effectively analyze the electronic circuit and to take preemptive actions or to debug based on the analysis

Logic Analyzers may be broadly classified as external logic analyzers and embedded logic analyzers. The embedded logic analyzer is generally included within a programmable logic device or an integrated circuit (IC) e.g., a complex programmable gate array (CPLD), field Programmable gate array (FPGA), application specific integrated circuit (ASIC) etc. The embedded logic analyzer has the ability to capture large amounts of high speed data signals within the IC.

The embedded logic analyzer may include a memory to store the captured data signals. Usually, the embedded logic analyzer is programmable to capture and store the data signals specified by the user. The data signals stored by the embedded logic analyzer may be transferred to a computer for further analysis. The data signals are generally transferred to the computer through an interface provided on the IC.

FIG. 1 is a block diagram of a conventional embedded logic analyzer (ELA) 100 included within an integrated circuit (not shown). The ELA 100 includes an interconnect module 110 to receive a plurality of data signals within the integrated circuit. The interconnect module 11l is programmable to select a plurality of signals to be sampled and at least one trigger signal to enable sampling from the plurality of received signals. The at least one trigger signal is transferred to a trigger module 120. The trigger module 120 is programmable to set a trigger condition and to detect if the at least one trigger signal satisfies the trigger condition. If the trigger condition is satisfied, the trigger module 120 initiates a sampling process. Upon the initiation of the sampling process, a memory controller 130 starts sampling the plurality of signals to be sampled from the interconnect module 110. The sampled signals may be stored in a memory 140 for further analysis. Therefore, the ELA I 00 operates to execute a general code given below:

IF (<TRIGGER CONDITION>) THEN (SAMPLE SIGNALS(X)),

wherein the TRIGGER CONDITION is any logical operation or a series of logical operations and the SIGNALS (X) are the plurality of signals to be sampled from the interconnect module 110. According to the code executed by the ELA 100, when the trigger condition is satisfied, the ELA 100 samples at least one sampled signal and stores the sampled signal in the memory 140.

However, if it is desired to execute an action other than sampling when the trigger condition is satisfied, the ELA fails to execute that desired action. Further, conventional ELAs do not capture, analyze, and or debug software data or firmware data signals within the IC, and additional instrument(s) may be necessary in order to analyze these types of data. Additionally, in order to program the ELA or to analyze the data stored within the ELA, the user is required to be present at a workstation where the ELA is installed.

It would be desirable therefore to provide an ELA with enhanced analyzing and debugging capabilities to obviate the above-mentioned problems,

### SUMMARY OF THE INVENTION

Disclosed herein is an integrated circuit having a logic analyzer for receiving a plurality of signals from a plurality of busses. The plurality of signals includes at least one trigger signal and at least one sampled signal, and the logic analyzer comprises an interconnect module that receives the plurality of signals and selects at least one of the at least one trigger signal and the at least one sampled signal from the plurality of received signals, a trigger module to set at least one trigger condition and to detect if the at least one trigger signal satisfies the at least one trigger condition, an output module to perform at least one task based upon the satisfaction of at least one trigger condition, and a sampling controller for sampling the at least one sampled signal if the output module initiates a sampling process.

In a further form the at least one task is selected from a group of tasks that includes initiating a sampling process, modifying at least one signal from the plurality of received signals, and modifying the at least one trigger condition,

In another embodiment, the integrated circuit includes a memory communicatively coupled to the logic analyzer for storing the plurality of to-be sampled signals sampled by the sampling controller. In a further embodiment, the memory is included in the logic analyzer.

In another embodiment, the integrated circuit includes a network access device in electronic communication with the logic analyzer and a remote host, wherein the remote host is capable of programming the logic analyzer. In still another embodiment, the integrated circuit includes a network access device in electronic communication with the logic analyzer and a remote host, wherein the remote host is capable of analyzing the plurality of sampled signals.

In yet another embodiment, the integrated circuit includes a central processing unit (CPU) that supplies a plurality of data signals to the logic analyzer and an interface in electrical communication with the CPU and the logic analyzer. The interface includes a storage medium configured to store the plurality of data signals from the CPU and a plurality of communication lines in electrical communication with the CPU and the storage medium for supplying the plurality of data signals from the CPU to the storage medium such that the plurality of data signals stored in the storage medium are supplied to the interconnect module through the plurality of buses.

In one form, the trigger condition includes a series of logical operations.

In another embodiment, the integrated circuit is disposed into an apparatus being diagnosed.

In a further form, the interconnect module is a multiplexer. In still another form, the output module is a field programmable gate array. In yet another form, the sampling controller samples the sampled signal from the interconnect module.

In a further form, the output module instructs a controller associated with the integrated circuit to modify the at least one signal from the plurality of signals received by the logic analyzer.

In yet another embodiment, the integrated circuit includes a communication port such that the logic analyzer is programmable through the communication port.

In a further form, the plurality of data signals includes at least one of a software data signal and a firmware data signal.

In another aspect, an integrated circuit comprises a logic analyzer for receiving a plurality of signals from a plurality of buses within the integrated circuit. The plurality of signals includes at least one trigger signal and a plurality of to-be sampled signals, and the logic analyzer includes an interconnect module for receiving the plurality of signals and selecting the at least one trigger signal and the plurality of to-be sampled signals from the plurality of received signals, a trigger module for setting at least one trigger condition and detecting if the at least one trigger signal satisfies the at least one trigger condition to initiate a sampling process, and a sampling controller for sampling the plurality of to-be sampled signals when the sampling process is initiated by the output module. The integrated circuit also includes a processor for receiving a plurality of data signals within the integrated circuit. The processor is communicatively coupled to the trigger module to detect if the at least one trigger is satisfied by the at least one trigger signal such that if the at least one trigger condition is satisfied, the processor modifies at least one signal from the plurality of signals received by the processor.

In yet another aspect, an integrated circuit comprises a logic analyzer for receiving a plurality of signals from a plurality of buses within the integrated circuit, and the plurality of signals includes at least one trigger signal and at least one sampled signals. The logic analyzer comprises an interconnect module for receiving the plurality of signals and selecting at least one of the trigger signal and the sampled signal from the plurality of received signals, a trigger module for setting at least one trigger condition and if the at least one trigger signal satisfies the at least one trigger condition, initiating a sampling process, and a sampling controller for sampling the sampled signal when the sampling process is initiated by the trigger module. The integrated circuit also includes a CPU for supplying a plurality of data signals to the logic analyzer and an interface in communicatively coupled to the CPU and the logic analyzer. The interface includes a storage medium that is configured to store the plurality of data signals from the CPU and a plurality of communication lines in electrical communication with the CPU and the storage medium to supply the plurality of data signals from the CPU to the storage medium such that the plurality of data signals stored in the storage medium are supplied to the logic analyzer through the plurality of buses.

Additional features and advantages of the invention will be set forth in the detailed description which follows, and in part will be readily apparent to those skilled in the art from that description or recognized by practicing the invention as described herein including the detailed description which follows, the claims, as well as the appended drawings.

It is to be understood that both the foregoing general description and the following detailed description of the present embodiments of the invention and are intended to provide an overview or framework for understanding the nature and character of the invention as it is claimed. The accompanying drawings are included to provide a further understanding of the invention and are incorporated into and constitute a part of this specification. The drawings illustrate various embodiments of the invention and together with the description serve to explain the principles and operation of the invention.

### BRIEF DESCRIPTION OF THE DRAWINGS

The above-mentioned and other features and advantages of the various embodiments of the invention, and the manner of attaining them, will become more apparent will be better understood by reference to the accompanying drawings, wherein:

FIG. 1 is a block diagram of a conventional embedded logic analyzer;

FIG. 2 is a block diagram of one embodiment of an integrated circuit including a logic analyzer according to the present invention;

FIG. 3 is a block diagram of an apparatus embedding the integrated circuit of FIG. 2;

FIG. 4 is a block diagram illustrating a network access device coupling a remote host to the integrated circuit of FIG. 2;

FIG. 5 is a block diagram illustrating an interface to supply soft signals to the logic analyzer included on the integrated circuit of FIG. 2;

FIG. 6 is a block diagram, illustrating an interface configured to supply soft signals to the logic analyzer of FIG. 1 according to the present invention;

FIG. 7 is a block diagram showing a processor in communication with the logic analyzer included within the integrated circuit of FIG. 2; and

FIG. 8 is a flow chart illustrating the actions performed to capture software signals within the integrated circuit of FIG. 2 according to the present invention.

### DETAILED DESCRIPTION

Reference will now be made in detail to the exemplary embodiment(s) of the invention, as illustrated in the accompanying drawings. Whenever possible, the same reference numerals will be used throughout the drawings to refer to the same or like parts.

The present invention is directed to a programmable embedded logic analyzer included within an integrated circuit having enhanced analyzing and debugging capabilities. FIG. 2 illustrates one embodiment of an embedded logic analyzer (ELA) 200 disposed on an integrated circuit (IC) 260. The ELA 200 includes an interconnect module 210 that is programmable to select at least one of a plurality of candidate signals within the IC 260. The plurality of candidate signals selected by the interconnect module 210 may include at least one trigger signal and/or at least one signal to be sampled (i.e., a sampled signal). The interconnect module 210 routes the at least one trigger signal to a trigger module 220. The trigger module 220 detects if the at least one trigger signal satisfies at least one trigger condition specified by a user. If the trigger condition is satisfied, an output module 230 performs at least one task. For example, the output module 230 may modify at least one signal within the IC 260.

The IC 260 includes a plurality of buses 265 that carries the plurality of candidate signals. The plurality of signals includes at least one sampled signal) and at least one trigger signal. The interconnect module 210 receives the plurality of signals from the plurality of buses 265. The interconnect module 210 is programmable to select at least one sampled signal and/or at least one trigger signal from the plurality of received signals. Essentially, the interconnect module 210 selects the sampled signal(s) and/or trigger signal(s) specified by a user. In one embodiment, the interconnect module 210 may be a multiplexer.

The interconnect module 210 routes the trigger signal to the trigger module 220. The trigger module 220 is programmable to set the trigger condition. The trigger condition may be a single logical operation (e.g., a simple event) or a series of logical operations (e.g., a complex series of events a finite state machine). The trigger module 220 detects if the at least one trigger condition is satisfied by the trigger signal. If the trigger condition is satisfied, the trigger module 220 provides an information to the output module 230.

The output module 230 performs at least one task from a group of tasks based upon, in response to, or as a result of the satisfaction of the at least one trigger condition. The group of tasks may include modifying at least one signal from the plurality of received signals, modifying the at least one trigger condition, and initiating a sampling process. In one embodiment, the output module 230 is an field programmable gate array.

If the output module 230 initiates the sampling process, a sampling controller 240 starts sampling the sampled signal from the interconnect module 210. The sampled signal sampled by the sampling controller 240 may be stored in a memory 250. The signals stored in a memory 250 may be transferred to a computer (not shown) for analysis. Such signal transfer to the computer may occur through a communication port 280 such as a USB port. The signals transferred to the computer may then be analyzed by the user,

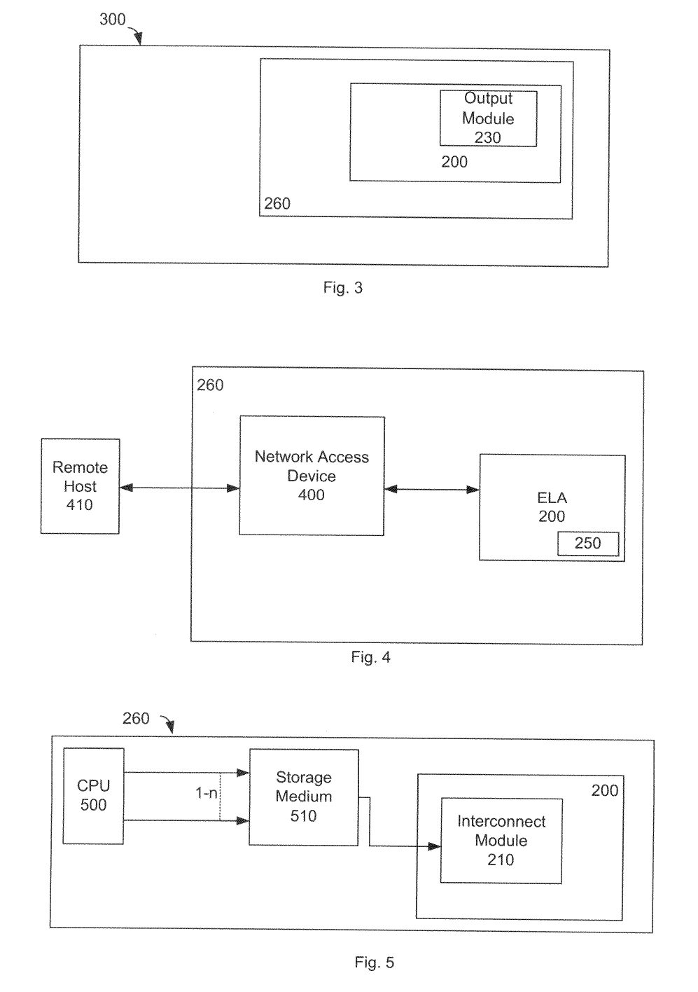

While FIG. 2 shows that the memory 250 resides in the ELA 200, it will be appreciated by one of ordinary skill in the art that the memory may be a separate component on the integrated circuit 260 in another embodiment. In yet another embodiment, the memory may be a located separately from the integrated circuit 260, provided that it remains communicatively coupled to the ELA. After analyzing the signals, at least one action within an apparatus 300 embedding the IC 260, as shown in FIG. 3, may be performed by configuring or programming the output module 230 to perform a specific task based upon the analysis. For example, the user may debug an error or fault or correct the action of a component of the apparatus 300. Therefore, the apparatus 300 can be diagnosed more effectively to ensure proper functioning of the apparatus 300. In one embodiment, the apparatus 300 may be an imaging device such as a printer, a scanner, or a multi-function device which has the ability to print, scan, fax and/or copy.

The output module 230 may be programmed or configured to modify at least one signal based upon, in response to, or as a result of the satisfied trigger condition. If the satisfied trigger condition indicates an error, the output module 230 may modify at least one signal from the plurality of signals received by the ELA 200 to correct the indicated error. For example, if a value of signal ‘X’ has to be 30 for error-free operation of the apparatus 300, and if the trigger condition X≠30 is satisfied, the output module 230 modifies the value of signal X to bring the value of the signal to 30 for error free operation of the apparatus 300.

The output module 230 may also instruct a controller 270 (shown in FIG. 2) to modify at least one signal from the plurality of signals received by the ELA 200 to correct the indicated error. For example, the output module 230 may instruct the controller 270 to turn off a pulse width modulator (PWM) if the PWM that regulates the speed of a motor is detected to be stuck, hereby preventing damage to the motor. The output module 230 may also be capable of stopping a direct memory access (DMA) operation. In addition, the output module 230 may modify the trigger condition, if required. These capabilities of the output module 230 greatly enhance the debugging power of the ELA 200. Therefore, the ELA 200 generally executes a code given below:

IF (<CONDITION>) THEN (<ACTION(S)>),

wherein ACTION(S) is at least any one of the above mentioned actions performed by the output module or the controller, and CONDITION is the trigger condition set by the user.

In one embodiment, as shown in FIG. 4, the IC 260 includes a network access device 400. The network access device 400 is in communicatively coupled to the ELA 200 and is connected to a remote host 410 directly or through a network. The connection may include a wired connection and/or a wireless connection, and the network may be the Internet, a local area network, a wide area network or a metropolitan area netvork. The remote host 410 is capable of programming the ELA 200 within the IC 260. The remote host 410 is also capable of analyzing the sampled signals stored in memory. The remote host 410 accesses the ELA 200 through the network access device 400.

The ELA 200 may be programmed to automatically and periodically send the stored sampled signals to the remote host 410 for analysis. For example, the ELA 200 embedded within a printer may be programmed to automatically and periodically send an encoder signal to the remote host 410. The encoder signal indicates the motion of the motor within the printer. If it is determined that the encoder signals are decaying or going into a bad state, a remote user may provide instruction to service the printer. In one embodiment, the ELA 200 is programmable to transfer stored data signals to the remote host 410 if such instruction or command is received from the remote host 410.

In another embodiment, as illustrated in FIG. 5, the IC 260 includes a central processing unit (CPU) 500. The CPU 500 provides a plurality of data signals to the ELA 200. The data signals may be hardware, software or firmware signals. The data signals are supplied from the CPU 500 to the ELA 200 through an interface. The interface is in communicatively coupled to the CPU 500 and the ELA 200. The interface includes a storage medium 510 and a plurality of communication lines (1-n). The plurality of communication lines are in communicatively coupled with the CPU 500 and the storage medium 510. The plurality of communication lines (1-n) is configured to supply the plurality of data signals from the CPU 500 to the storage medium 510. The storage medium 510 is configured to store the plurality of data signals.

Each data signal from the plurality of data signals is associated with a data field and an address field. The data field provides the value of the data signal to be stored and the address field specifies a location in the storage medium 510 where the data signal has is stored. The storage medium 510 includes a plurality of memory locations. Each of the plurality of memory locations has a unique address. The plurality of data signals stored in the storage medium 510 is supplied to the interconnect module 210 through the plurality of buses on the IC 260. Essentially, the storage medium 510 is in electrical communication with the plurality of buses on the IC 260 to supply the stored data signals to the interconnect module 210.

The stored data signals supplied to the interconnect module 210 includes the hardware, software and /or firmware data signals. The data signals include a plurality of sampled signals and at least one trigger signal. The interconnect module 210 selects the plurality of sampled signals and at least one trigger signal from the plurality of received data signals. The trigger signal is supplied to the trigger module 220. The trigger module 220 detects if the trigger signal satisfies at least one trigger condition. If the trigger condition is satisfied, the sampling controller 240 samples the plurality of sampled signals from the interconnect module 210. The plurality of sampled signals is stored in the memory 250. The plurality of stored signals along with other stored signals is transferred to the computer for analysis. Therefore, the software, hardware and or firmware signals can be analyzed simultaneously on the computer.

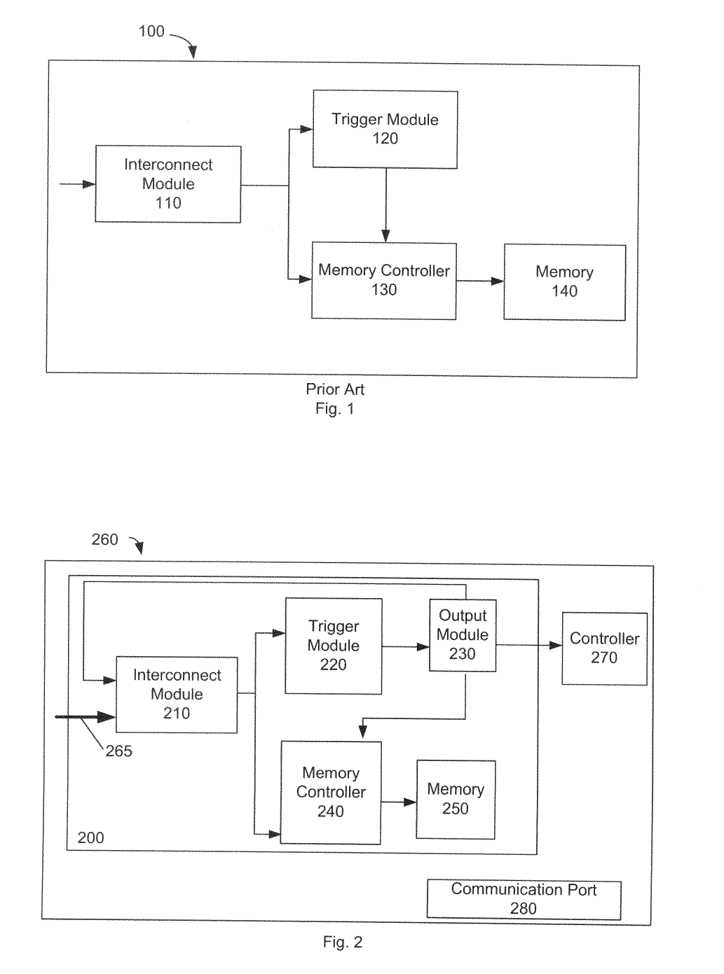

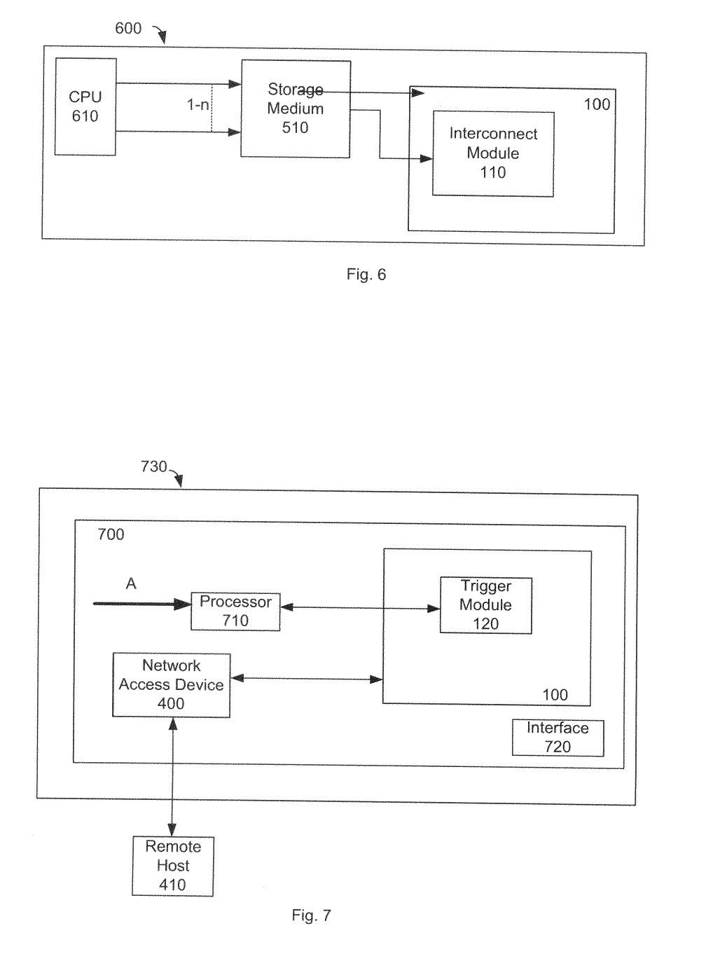

In another embodiment, as illustrated in FIG. 6, the interface i.e., the plurality of communication lines (1-n) and the storage medium 510 are disposed on an IC 600. The IC 600 includes the ELA 100 of FIG. 1 and a CPU 610. The CPU 610 supplies the plurality of data signals to the ELA 100. The plurality of data signals includes at least one software or firmware data signal. The plurality of data signals are supplied from the CPU 610 to the ELA 100 through the plurality of communication lines (1-n) and the storage medium 510. The plurality of communication lines (1-n) is configured to supply the plurality of data signals from the CPU 610 to the storage medium 510. The storage medium 510 is configured to store the plurality of data signals. The data signals stored in the storage medium 510 are supplied to the interconnect module 110 through the plurality of buses on the IC 600. Essentially, the storage medium 510 is in electrical communication with the plurality of buses on the IC 600 to supply the stored data signals to the interconnect module 110.

In yet another embodiment, as illustrated in FIG. 7, the ELA 100 is disposed on an IC 700 that includes a processor 710. The processor 710 receives a plurality of signals from a plurality of buses on the IC 700. Such signals may be any combination of hardware, software and/or firmware signals (indicated by arrow A) within the IC 700. The processor 710 is communicatively coupled to the ELA 100 disposed on the IC 700. More specifically, processor 710 may be communicatively coupled to the trigger module 120 of the ELA 100.

In an alternate embodiment, the IC 700 may be communicatively coupled to the ELA 200 of FIG. 2. In this embodiment, the processor 710 receives at least one trigger signal from the trigger module 220 to detect if at least one trigger condition is satisfied. If at least one trigger condition is satisfied, the processor 710 modifies at least one signal from the plurality of data signals received by the processor 710. The processor 710 is also programmable to modify at least one trigger condition in the trigger module 220 when the at least one trigger condition is satisfied. The processor 710 is programmable through an interface 720 provided on the IC 700.

The IC 700 may include the network access device 400. The network access device 400 communicatively couples the IC 700 to the remote host 410. The remote host 410 can program the ELA 100 disposed on the IC 700. The remote host 410 can also analyze the sampled signals stored in the ELA 100. Therefore, the remote host 410 can diagnose an apparatus 730 embedding the ELA 100 and the network access device 400.

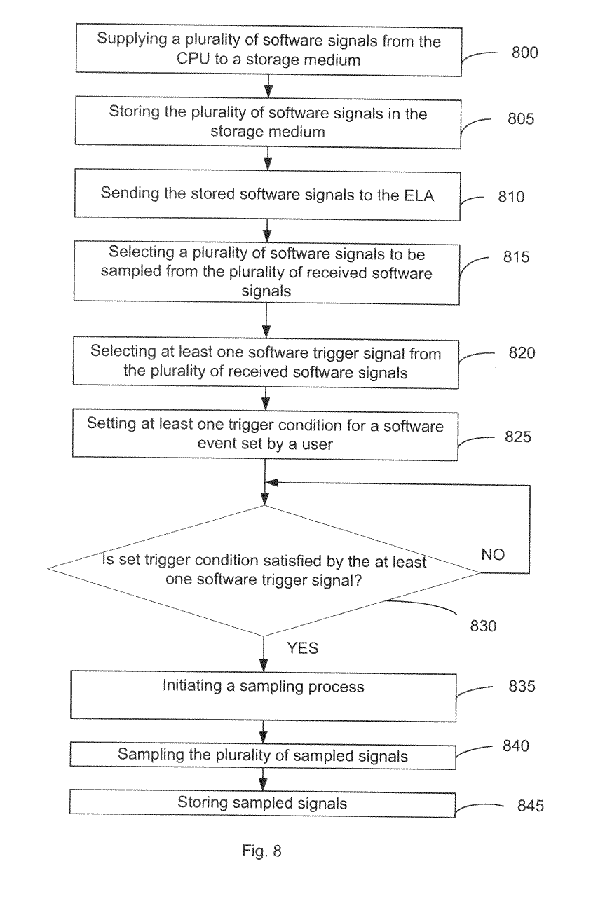

FIG. 8 is a flowchart illustrating a method for capturing software signals or events within the IC 260. The CPU 500 disposed on the IC 260 supplies a plurality of software signals to the storage medium 510 at block 800. The storage medium is configured to store the plurality of software signals (block 805). The storage medium 510 sends the stored software signals to the interconnect module 210 of ELA 200 at block 810. The interconnect module 210 is programmed to select a plurality of software signals that is to be sampled from the plurality of received software signals (block 815). The interconnect module 210 is also programmed to select at least one software trigger signal from the plurality of received software signals (block 820). The user sets within the trigger module 220 at least one trigger condition for a software event (block 825). The trigger module 220 detects if the set trigger condition is satisfied by the at least one software trigger signal (block 830). If the trigger condition is satisfied, the trigger module 220 initiates the sampling process at block 835. Otherwise, the trigger module repeats the detection of a satisfied set trigger condition.

Upon the initiation of the sampling process, the sampling controller 240 samples the plurality of software signals that is to be sampled from the interconnect module 210 (block 840). The sampled software signals may then be stored in the memory 250 at block 845. The stored software signals may also be transferred to the computer for analysis by a program running on the computer or by a user.

It will be appreciated by one of ordinary skill in the art the present invention is not limited to software signals. Rather other signals, such as hardware and firmware, may be captured instead of and or in combination with software signals.

It will be apparent to those skilled in the art that various modifications and variations can be made to the present invention without departing from the spirit and scope of the invention. Thus it is intended that the present invention cover the modifications and variations of this invention provided they come within the scope of the appended claims and their equivalents.

1. In an integrated circuit, a logic analyzer for receiving a plurality of signals from a plurality of buses, the plurality of signals including a trigger signal and a sampled signal, the logic analyzer comprising:
an interconnect module for receiving the plurality of signals and selecting at least one of the trigger signal and the sampled signal from the plurality of received signals;
a trigger module for setting at least one trigger condition and detecting if the trigger signal satisfies the at least one trigger condition;
an output module for performing at least one task based upon the satisfaction of the at least one trigger condition; and
a sampling controller for sampling the sampled signal when a sampling process is initiated by the output module.

2. The integrated circuit of claim 1, wherein the at least one task is selected from a group of tasks consisting of initiating the sampling process, modifying at least one signal from the plurality of received signals, and modifying the at least one trigger condition.

3. The integrated circuit of claim 1, the output module instructs a controller associated with the integrated circuit to modify at least one signal from the plurality received signals.

4. The integrated circuit of claim 1, further comprising a memory communicatively coupled to the logic analyzer for storing the sampled signal.

5. The integrated circuit of claim 1, wherein the logic analyzer further comprises a memory for storing the sampled signal.

6. The integrated circuit of claim 1, further comprising a network access device in electronic communication with the logic analyzer and a remote host, the remote host being capable of programming the logic analyzer.

7. The integrated circuit of claim 1, further comprising a network access device communicative y coupled to the logic analyzer and a remote host, the remote host being capable of analyzing the sampled signal.

8. The integrated circuit of claim 1, further comprising:
a central processing unit for supplying a plurality of data signals to the logic analyzer; and
an interface in electrical communication with the central processing unit and the logic analyzer, the interface having:
a storage medium configured to store the plurality of data signals from the central processing unit; and
a plurality of communication lines in communicatively coupled to the central processing unit and the storage medium for supplying the plurality of data signals from the central processing unit to the storage medium, wherein the plurality of data signals stored in the storage medium are being supplied to the interconnect module through the plurality of buses.

9. The integrated circuit of claim 1, wherein the at least one trigger condition includes a series of logical operations.

10. The integrated circuit of claim 1, wherein the integrated circuit is disposed into an apparatus being diagnosed.

11. The integrated circuit of claim 1, wherein the interconnect module is a multiplexer.

12. The integrated circuit of claim 1, wherein the output module is a field programmable gate array.

13. The integrated circuit of claim 1, wherein the sampling controller samples the sampled signal from the interconnect module.

14. The integrated circuit of claim 1, wherein the output module instructs a controller associated with the integrated circuit to modify at least one signal from the plurality of signals received by the logic analyzer.

15. The integrated circuit of claim 1, further comprising a communication port such that the logic analyzer is programmable through the communication port.

16. The integrated circuit of claim 8, wherein the plurality of data signals includes at least one of a software data signal and a firmware data signal.

17. An integrated circuit comprising:
a logic analyzer for receiving a plurality of signals from a plurality of buses within the integrated circuit the plurality of signals including at least one trigger signal and at least one sampled signal, the logic analyzer comprising;
an interconnect module for receiving the plurality of signals and selecting the at least one of the at least one trigger signal and the at least one sampled signal from the plurality of received signals;
a trigger module for setting at least one trigger condition and detecting if the at least one trigger signal satisfies the at least one trigger condition to initiate a sampling process; and
a sampling controller for sampling the at least one sampled signal when the sampling process is initiated by the trigger module;
and
a processor receiving a plurality of data signals within the integrated circuit, the processor is communicatively coupled to the trigger module to detect if the at least one trigger condition is satisfied by the at least one trigger signal, and wherein if the at least one trigger condition is satisfied the processor modifies at least one signal from the plurality of signals received by the processor.

18. The integrated circuit of claim 17, further comprising a memory communicatively coupled to the logic analyzer for storing the at least one sampled signal sampled by the sampling controller.

19. The integrated circuit of claim 17, further comprising a network access device in electronic communication with the logic analyzer and a remote host, the remote host being capable of programming the logic analyzer and analyzing the at least one sampled signal stored in a memory.

20. The integrated circuit of claim 17, wherein the at least one trigger condition includes a series of logical operations.

21. The integrated circuit of claim 17, wherein the sampling controller samples the at least one sampled signal from the interconnect module.

22. The integrated circuit of claim 17, wherein the processor is programmable to modify the trigger condition when the at least one trigger condition is satisfied.

23. The integrated circuit of claim 17, wherein the interconnect module is a multiplexer.

24. An integrated circuit comprising:
a logic analyzer for receiving a plurality of signals from a plurality of buses within the integrated circuit, the plurality of signals including a trigger signal and a sampled signal, the logic analyzer comprising:
an interconnect module for receiving the plurality of signals and selecting the at least one of the trigger signal and the sampled signal from the plurality of received signals;
a trigger module for setting at least one trigger condition and if the trigger signal satisfies the at least one trigger condition, initiating a sampling process; and
a sampling controller for sampling the sampled signal when the sampling process is initiated by the trigger module;
a central processing unit for supplying a plurality of data signals to the logic analyzer; and
an interface communicatively coupled to the central processing unit and the logic analyzer, the interface having:
a storage medium configured to store the plurality of data signals from the central processing unit; and
a plurality of communication lines communicatively coupled to the central processing unit and the storage medium to supply the plurality of data signals from the central processing unit to the storage medium, wherein the plurality of data signals stored in the storage medium are supplied to the interconnect module through the plurality of buses.
